(19) United States
(12) Patent Application Publication
(10) Pub. No.: US 2012/0012828 A1
(43) Pub. Date: Jan. 19, 2012

(54) ORGANIC LIGHT-EMITTING DEVICE

(75) Inventors: Sung-Soo Koh, Yongin-City (KR); Chul-Woo Jeong, Yongin-City (KR); Hee-Seong Jeong, Yongin-City (KR); Soon-Ryong Park, Yongin-City (KR); Woo-Suk Jung, Yongin-City (KR); Il-Ryong Cho, Yongin-City (KR); Tae-Kyu Kim, Yongin-City (KR); Jae-Yong Kim, Yongin-City (KR)

(73) Assignee: Samsung Mobile Display, Co., Ltd., Yongin-City (KR)

(21) Appl. No.: 13/184,301

(22) Filed: Jul. 15, 2011

(30) Foreign Application Priority Data
Jul. 16, 2010 (KR) 10-2010-0069171

(51) Int. Cl. H01L 51/52

(52) U.S. Cl. 257/40; 257/E51.018

(57) ABSTRACT

An organic light-emitting device includes a substrate; an encapsulation substrate; an organic light-emitting unit interposed between the substrate and the encapsulation substrate; and a layer having an UV shielding capability interposed between the encapsulation substrate and the organic light-emitting unit.

### CLAIM OF PRIORITY

This application makes reference to, incorporates the same herein, and claims all benefits accruing under 35 U.S.C. §119 from an application for ORGANIC LIGHT-EMITTING DEVICE earlier filed in the Korean Intellectual Property Office on 16 Jul. 2010 and there duly assigned Serial No. 10-2010-0069171.

### BACKGROUND OF THE INVENTION

1. Field of the Invention

The present invention relates to an organic light-emitting device including a layer having an UV shielding capability between An encapsulation: substrate and an organic light-emitting unit.

2. Description of the Related Art

A polarizing plate includes, in general, a polarizing film formed of a polyvinyl alcohol resin to which orientated pigments are adsorbed, a protection film (for example, a protection film formed of acetic acid cellulose such as triacetyl cellulose (TAC)), and an adhesive layer interposed either between one surface of the polarizing film and the protection film or between both surfaces of the polarizing film and the protection film. The polarizing plate having such a structure described above is attached to a liquid crystal cell using an adhesive and if necessary, other optical films may be further interposed between the polarizing plate and the liquid crystal cell.

Liquid crystal display apparatuses are increasingly used as thin film display apparatuses in liquid crystalline televisions, liquid monitors, and personal computers. In particular, more liquid crystalline televisions are sold and the demand for inexpensive liquid crystalline televisions is increasing. A polarizing plate for a liquid crystalline television has a typical structure including a polarizing film formed of a polyvinyl alcohol resin to which orientated pigments are adsorbed, a TAC film attached to both sides of the polarizing film using an aqueous adhesive, and a retardation film attached to an outer surface of one side of the polarizing plate using an adhesive.

Examples of retardation films deposited on polarizing films are an elongation product of a polycarbonate resin film and an elongation product of a cycloolefin resin film. The cycloolefin resin film is widely used for liquid crystalline televisions since the cycloolefin resin film has small irregularities in phase difference at high temperatures. In order to improve productivity and decrease manufacturing costs, there is a need to simplify a polarizing plate and a retardation film including a cycloolefin resin film and to reduce the manufacturing processes therefor.

### SUMMARY OF THE INVENTION

The present invention provides an organic light-emitting device including an layer having at least one capability selected from a group consisting of an UV shielding capability and a polarizing capability.

According to an aspect of the present invention, there is provided an organic light-emitting device including a substrate; an encapsulation substrate; an organic light-emitting unit interposed between the substrate and the encapsulation substrate; and a layer having an ultraviolet (UV) shielding capability interposed between the encapsulation substrate and the organic light-emitting unit.

The layer further has a polarizing capability.

The layer contacts a surface of the encapsulation substrate.

The layer contacts a surface of the organic light-emitting unit.

The layer is spaced apart from both the encapsulation substrate and the organic light-emitting unit.

The layer contacts a surface of the encapsulation substrate, and the surface of the encapsulation substrate contacting the layer has a cavity structure or a trench structure, each of which is formed by etching.

An adhesive is applied to the layer having an UV ray shielding capability and the total thickness of the formed adhesive layer and the layer is in a range of about 20 μm to about 100 μm.

An adhesive is applied to the layer having an UV shielding capability and a polarizing capability, and the total thickness of the formed adhesive layer and the layer is in a range of about 220 μm to about 300 μm.

An anti-reflection coating film is further formed on the encapsulation substrate.

### BRIEF DESCRIPTION OF THE DRAWINGS

A more complete appreciation and advantages of the present invention will become, more apparent by the following detailed description along with detail exemplary embodiments thereof with reference to the accompanying drawings in which:

FIG. 1 is a schematic sectional view of an organic light-emitting device constructed as an embodiment of the present invention;

FIG. 2 is a schematic sectional view of an organic light-emitting device constructed as another embodiment of the present invention; and

FIG. 3 is a schematic sectional view of an organic light-emitting device constructed as another embodiment of the present invention.

### DETAILED DESCRIPTION OF THE INVENTION

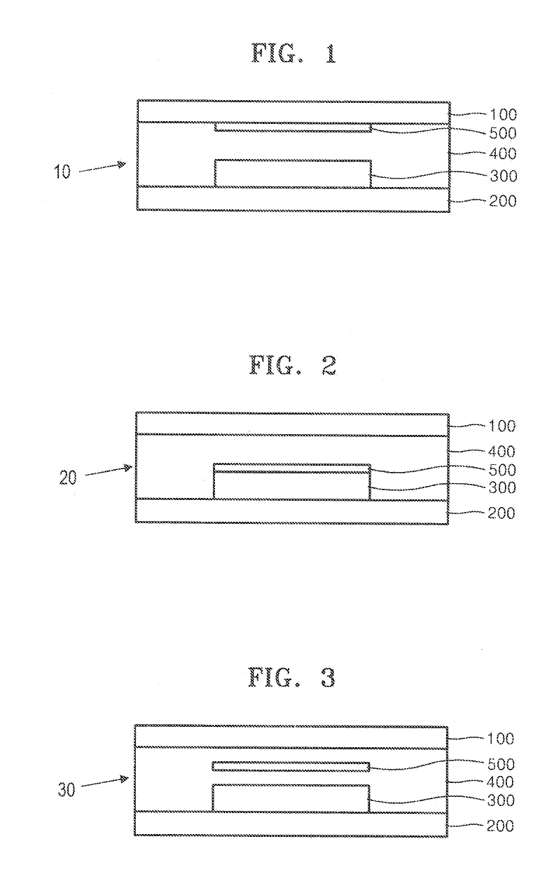

The general inventive concept is described in detail below with reference to the accompanying drawings. In this regard, the present invention may be modified in various ways and should not be construed as being limited to the embodiments. Like reference numerals in the drawings of FIG. 1 through FIG. 3 designate like elements throughout the specification, and thus their description have not been repeated.

An organic light-emitting device according to an embodiment of the present invention includes a substrate, an encapsulation substrate, an organic light-emitting unit interposed between the substrate and the encapsulation substrate, and a layer having an ultraviolet (UV) shielding capability interposed between the encapsulation substrate and the organic light-emitting unit.

FIG. 1 is a schematic sectional view of an organic light-emitting device according to an embodiment of the present invention.

As shown in FIG. 1, an organic light-emitting device 10 according to an exemplary embodiment of the present invention includes a substrate 200, an encapsulation substrate 100, an organic light-emitting unit 300 interposed between the substrate 200 and the encapsulation substrate 100, an encapsulation layer 400 and a layer 500 having an UV shielding capability interposed between the encapsulation substrate 100 and the organic light-emitting unit 300. The layer 500 contacts a surface of the encapsulation substrate 100 in FIG. 1.

The layer 500 of the organic light-emitting device 10 may further have a polarizing capability.

FIGS. 2 and 3 are schematic sectional views of organic light-emitting devices according to other exemplary embodiments of the present invention.

The organic light-emitting unit 300 includes a first electrode (anode), a hole injection layer (HIL), a hole transport layer (HTL), an emitting layer (EML), an electron transport layer (ETL), an electron injection layer (EIL), and a second electrode (cathode), which are not show in FIGS. 1, 2, and 3.

As shown in FIG. 2, a layer 500 having an UV shielding capability in an organic light-emitting device 20 contacts a surface of an organic light-emitting unit 300. As shown in FIG. 3, a layer 500 having an UV shielding capability in an organic light-emitting 30 is spaced apart from both an encapsulation substrate 100 and an organic light-emitting unit 300.

In regard to the organic light-emitting devices 10, 20, and 30 illustrated in FIGS. 1, 2, and 3, an anti-reflection (AR) coating film (not shown in the Figures) may be further formed on the encapsulation substrate 100, an adhesive film may be included in the organic light-emitting devices 10, 20 and 30.

According to an embodiment of the present invention, a layer having an UV shielding capability may further have a polarizing capability.

According to an embodiment of the present invention, a layer having at least one capability selected from a group consisting of an UV shielding capability and a polarizing capability may be included in the encapsulation layer 400 in an encapsulation process and then constitute the encapsulation layer 400.

After the encapsulation layer 400 is formed, the adhesive film is cured by irradiation of UV rays, and during the curing, the organic light-emitting unit 300 is protected from the UV rays by the layer having at least one capability selected from a group consisting of an UV shielding capability and a polarizing capability.

According to an embodiment of the present invention, in an organic light-emitting device, an layer having at least one capability selected from an group consisting of an UV shielding capability and a polarizing capability may be included in an encapsulation layer. Due to the inclusion of the layer, there is no need to form an additional film, such as a polarizing film, on an encapsulation substrate for a purpose of an optical or resistance-to-weather change after the encapsulation process.

According to an embodiment of the present invention, if necessary, a cavity structure or a trench structure may be formed in an inner a surface of an encapsulation substrate by etching, where a layer having at least one capability selected from a group consisting of an UV shielding capability and a polarizing capability is contacted on the inner surface, thereby allowing formation of the layer on the cavity structure or the trench structure of the encapsulation substrate. Thus, the thickness of the layer may be more reduced than that of a layer used in the art.

Typically, a layer attached to an encapsulation substrate has a thickness of about 130 μm. However, according to an embodiment of the present invention, the inner surface of the encapsulation substrate has a cavity structure or a trench structure formed by etching and thus, the thickness of the layer in the present invention may be reduced.

According to an embodiment of the present invention, an adhesive may be applied to a layer having an UV shielding capability, and the total thickness of the formed adhesive layer and the layer having an UV shielding capability may be in a range of about 20 μm to about 100 μm.

The range of the total thickness of the formed adhesive layer and the layer having an UV shielding capability is optimal in consideration of both the UV shielding capability and thicknesses of other layers of the organic light-emitting device.

According to an embodiment of the present invention, an adhesive may be applied to a layer having an UV shielding capability and a polarizing capability, and the total thickness of the formed adhesive layer and the layer having an UV shielding capability and a polarizing capability may be in a range of about 220 μm to about 300 μm.

The range of the total thickness of the formed adhesive layer and the layer having an UV shielding capability and a polarizing capability is optimal in consideration of both the UV shielding capability and the polarizing capability and thicknesses of other layers of the organic light-emitting device.

The formed adhesive layer may have a thickness of about 25 μm to about 35 μm, for example, about 30 μm.

In addition, when an anti-reflection (AR) coating film (not shown in the Figures) is formed on an encapsulation substrate (for example, a glass substrate) of an organic light-emitting device according to an embodiment of the present invention, a higher resistance-to-weather change and a stronger rigidity may be obtained than those obtained in a conventional organic light-emitting device.

Hereinafter, a method for manufacturing an organic light-emitting device according to an embodiment of the present invention is described in detail with reference to the organic light-emitting device of FIG. 2. As shown in FIG. 2, the organic light-emitting device 20 includes a substrate 200, an organic light-emitting unit 300 including a first electrode (anode), a hole injection layer (HIL), a hole transport layer (HTL), an emitting layer (EML), an electron transport layer (ETL), an electron injection layer (EIL), and a second electrode (cathode), which are sequentially arranged in the stated order on the substrate 200, an encapsulation layer 400 including a layer 500 that has at least one capability selected from a group consisting of an UV shielding capability and a polarizing capability, and an encapsulation substrate 100.

First, the first electrode material having a high work function is deposited or sputtered on the substrate 200 to form the first electrode. The first electrode may be an anode or a cathode. The substrate 200 is any of a variety of substrates that are used in a conventional organic light-emitting device, and may be a glass substrate or a transparent plastic substrate with excellent mechanical strength, thermal stability, transparency, surface smoothness, ease of handling, and water resistance. Examples of the first electrode material include materials, such as indium tin oxide (ITO), indium zinc oxide (IZO), tin oxide (SnO₂), zinc oxide (ZnO), aluminum (Al), silver (Ag), and magnesium (Mg), which have excellent conductivity. The first electrode may be formed as a transparent or reflective electrode.

Next, the HIL is formed on the first electrode by various methods, for example, by the methods of vacuum deposition, spin coating, casting, Langmuir-Blodgett (LB) deposition, or the like.

When the HIL is formed by vacuum deposition method, the deposition conditions may vary according to the material that is used to form the HIL, the structure and the thermal characteristics of the HIL. For example, the deposition conditions may include a deposition temperature between about 100° C. to about 500° C., a vacuum pressure between about 10⁻⁸ torr to about 10⁻³ torr, and a deposition rate between about 0.01 Å/sec to about 100 Å/sec.

When the HIL is formed by using spin coating method, the coating conditions may vary according to the material used to form the HIL, the structure and thermal properties of the HIL. For example, the coating conditions may include a coating speed sin a range of about 2000 rpm to about 5000 rpm, and a thermal treatment temperature in a range of about 80° C. to about 200° C., wherein the thermal treatment process serves to remove solvents after coating.

The HIL may be formed of any material that is commonly used to form a HIL. Examples of the materials that are used to form the HIL include a phthalocyanine compound such as copper phthalocyanine (CuPc), 4,4′,4″-tris(3-methylphenylphenylamino)triphenylamine (m-MTDATA), N,N′-di(1-naphthyl)-N,N′-diphenylbenzidine (NPB), N,N′-diphenyl-N,N′-bis-[4-(phenyl-m-tolyl-amino)-phenyl]-biphenyl-4,4′-diamine (DNTPD), TDATA, 2-TNATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline/poly(4-styrenesulfonate) (PANI/PSS), but are not limited thereto.

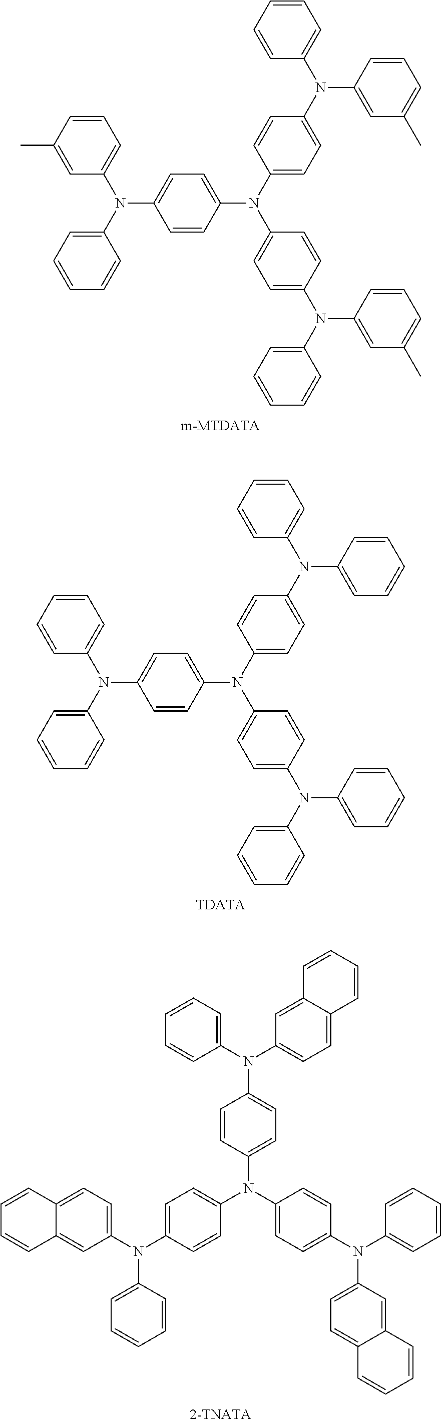

The HIL may have a thickness in a range of about 100 Å to about 10000 Å, more preferably, a thickness in a range of about 100 Å to about 1000 Å. When the thickness of the HIL is within these ranges, the HIL has good hole injection characteristics without an increase in driving voltage.

Next, the HTL is formed on the HIL by various methods, for example, by the methods of vacuum deposition, spin coating, casting, LB deposition, or the like. When the HTL is formed by either vacuum deposition method or spin coating method, the deposition conditions or the coating conditions of either the vacuum deposition method or the spin coating method may be similar to those applied to form the HIL, though the deposition conditions or the coating conditions may vary according to the material that is used to form the HTL.

The HTL may be formed of any known HTL material. Examples of the HTL materials include, but are not limited to, carbazole derivatives such as N-phenylcarbazole or polyvinylcarbazole, and amine derivatives having a condensed aromatic ring, such as 4,4′-bis[N-(1-naphthyl)-N-phenylamino]biphenyl (NPB), N,N′-bis(3-methylphenyl)-N,N′-diphenyl-[1,1-biphenyl]-4,4′-diamine (TPD), or the like.

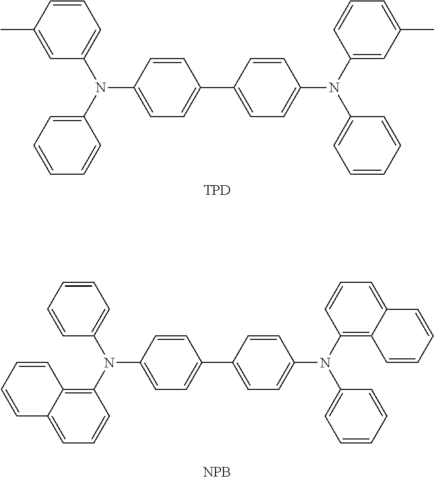

The HTL may have a thickness in a range of about 50 Å to about 1000 Å, preferably, a thickness in a range of about 100 Å to about 600 Å. When the thickness of the HTL is within these ranges, the HTL has excellent hole transport characteristics without a substantial increase in driving voltage.

Next, the EML is formed on the HTL by various methods, for example, by the methods of vacuum deposition, spin coating, casting, LB deposition, or the like. When the EML is formed by either vacuum deposition method or spin coating method, the deposition conditions or the coating conditions of either the vacuum deposition methods or the spin coating method may be similar to those used to form the HIL, though the deposition conditions or the coating conditions may vary according to the material that is used to form the EML.

The EML may be formed by using variety of well-known organic light-emitting materials, and the EML may also be formed by using a mixture of a well-known host and well-known dopants. The dopants may include either a fluorescent dopant or a phosphorescent dopant, which are widely known in the art. The dopants include red dopants, green dopants, and blue dopants.

Examples of the host include Tris(8-hydroxyquinolinato)aluminium (Alq₃), 4,4′-N,N′-dicarbazole-biphenyl (CBP), 9,10-di(naphthalene-2-yl)anthracene (ADN), and distyrylarylene (DSA), but are not limited thereto.

Examples of the red dopants include, but are not limited to, platinum(II) octaethyl-porphyrin (PtOEP), Ir(piq)₃, Btp₂Ir(acac), and DCJTB.

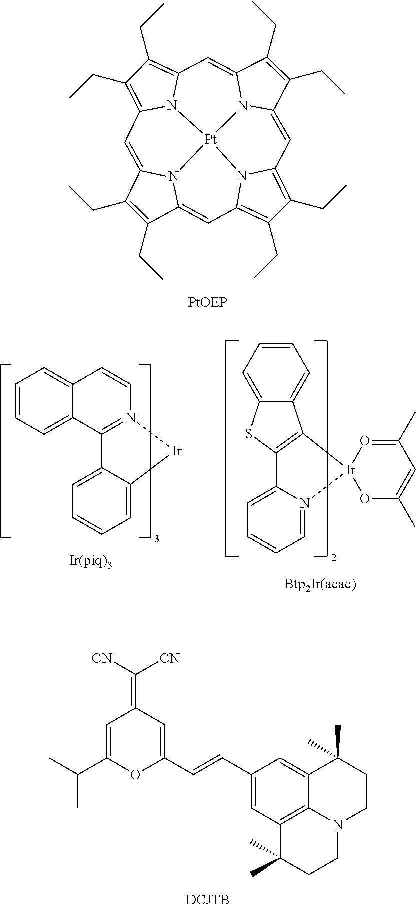

Examples of the green dopants may include, but are not limited to, Ir(ppy)₃ (where “ppy” denotes phenylpyridine), Ir(ppy)₂(acac), Ir(mpyp)₃, and, C545T.

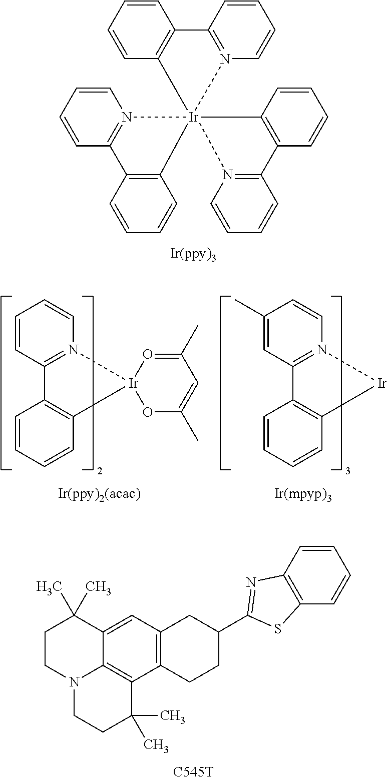

Examples of the blue dopants include F₂Irpic, (F₂ppy)₂Ir(tmd), Ir(dfppz)₃, ter-fluorene, 4,4′-bis(4-diphenylaminostyryl)biphenyl (DPAVBi), 4,4′-bis[2-[4-(N,N-diphenylamino)phenyl]vinyl]biphenyl (DPVBi), and 2,5,8,11-tetra-t-butyl phenylene (TBP), but are not limited thereto.

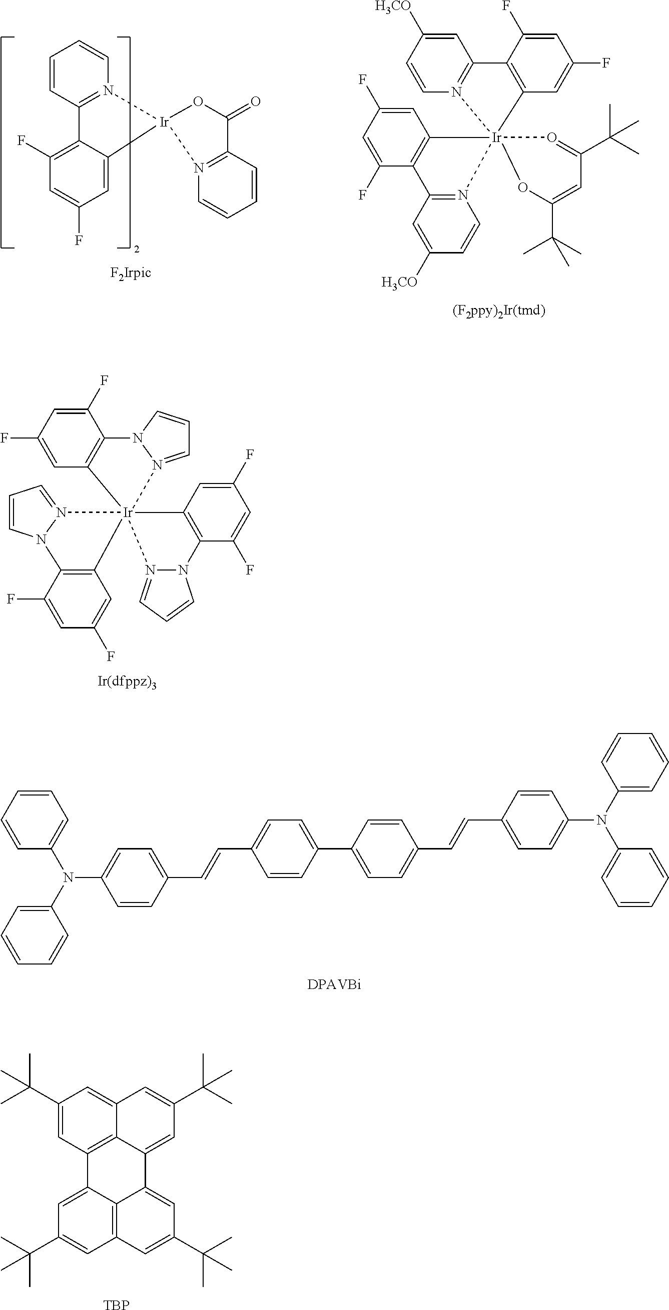

The amount of the dopants may be in a range of from about 0.1 to about 20 parts by weight, or about 0.5 to about 12 parts by weight, based on 100 parts by weight of the EML material, which is equivalent to the total weight of the host and the dopants. When the amount of the dopants is within these ranges, concentration quenching may be substantially prevented.

The EML may have a thickness of about 100 Å to about 1,000 Å, more preferably, about 200 Å to about 600 Å. When the thickness of the EML is within these ranges, the EML has good light-emitting characteristics without a substantial increase in driving voltage.

When the EML includes a phosphorescent dopant, a hole blocking layer (HBL) is formed on the EML in order to prevent diffusion of triplet excitons or holes into the ETL. In this case, the HBL may be formed of any material commonly used to form a HBL, without limitation. Examples of such HBL materials include, but are not limited to, oxadiazole derivatives, triazole derivatives, phenathroline derivatives, Bis-(2-methyl-8-quinolinolato)-4-(phenyl-phenplato)-aluminium-III (Balq), and 2,9-dimethyl-4,7-diphenyl-1,10-phenanthroline (BCP).

The HBL may have a thickness of about 50 Å to about 1,000 Å, more preferably, about 100 Å to about 300 Å. When the thickness of the HBL is within these ranges, the HBL has good hole shielding characteristics without a substantial increase in driving voltage.

Next, the ETL is formed on the EML (or HBL) by various methods, for example, by the methods of vacuum deposition, spin coating, casting, or the like. When the ETL is formed by either vacuum deposition method or spin coating method, the deposition or coating conditions may be similar to those applied to form the HIL, though the deposition or coating conditions may vary according to the materials that are used to form the ETL.

The ETL may be formed of any known materials used to form an ETL. Examples of electron transporting materials include, but are not limited to, quinoline derivatives, such as tris(8-quinolinorate)aluminum (Alq3), TAZ, BAlq, Bebq₂, or the like.

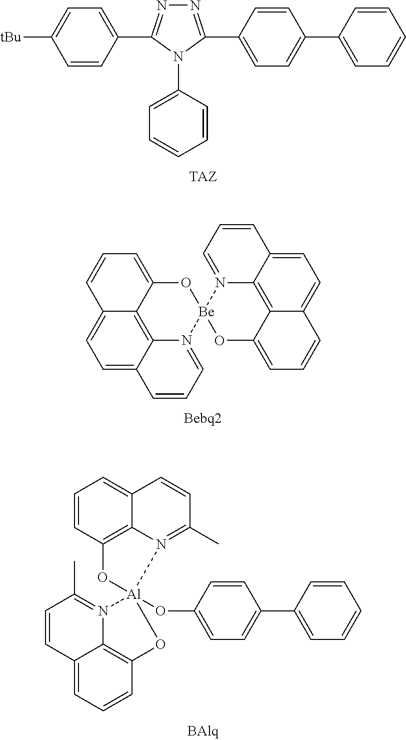

The ETL may have a thickness of about 100 Å to about 1,000 Å, more preferably, about 100 Å to about 500 Å. When the thickness of the ETL is within these ranges, the ETL has good electron transport characteristics without a substantial increase in driving voltage.

In addition, the EIL, which facilitates injection of electrons from the cathode, is formed on the ETL.

The EIL may be formed of LiF, NaCl, CsF, Li₂O, BaO, or the like, which are known in the art. The deposition or coating conditions may be similar to those applied to form the HIL, although the deposition and coating conditions may vary according to materials that are used to form the EIL.

The EIL may have a thickness of about 1 Å to 100 Å, more preferably, about 5 Å to about 90 Å. When the thickness of the EIL is within these ranges, the EIL has good electron injection characteristics without a substantial increase in driving voltage.

Finally, the second electrode is formed on the EIL by using, for example, vacuum deposition method, sputtering method, or the like. The second electrode may constitute a cathode or an anode. Materials for forming the second electrode may include a metal, an alloy, or an electrically conductive compound, which are low work function materials, or a mixture thereof. Examples of such materials include, but are not limited to, lithium (Li), magnesium (Mg), aluminum (Al), aluminum-lithium (Al—Li), calcium (Ca), magnesium-indium (Mg—In), and magnesium-silver (Mg—Ag). In addition, in order to manufacture a top-emission organic light-emitting device, a transparent cathode formed of a transparent material such as ITO or IZO may be used as the second electrode.

After forming the organic light-emitting unit 300 including the first electrode (anode), hole injection layer, hole transport layer, emitting layer, electron transport layer, electron injection layer and second electrode (cathode), the layer 500 is attached to the organic light-emitting unit 300 with an adhesive.

In an organic light-emitting device, an UV shielding capability or a polarizing capability is important in consideration of protection. According to an embodiment of the present invention, the layer 500 may be selectively included in the organic light-emitting device.

A commercially available UV shielding film, triacetylcellulose (TAC) film, an AR coating film, or a polarizing film all may be used as the layer 500.

The layer 500 may be used after being attached to the encapsulation substrate 100 in advance.

An adhesive may be applied to either a top or a bottom portion or both top and bottom portions of the layer 500. An available adhesive may be any adhesive that is used in the art.

The encapsulation substrate 100 is coupled to the layer 500 and then, UV rays are irradiated to the resultant structure, thereby completing the manufacturing of the organic light-emitting device.

Examples of the encapsulation substrate 100 may include all kinds of glass, including ground or non-ground glass.

According to an encapsulation technique using a film-type adhesive, at least one capability selected from a group consisting of an UV shielding capability and a polarizing capability is provided to a base film supporting the film-type adhesive film to shorten manufacturing process (for example, one step encapsulation process).

The encapsulation substrate 100 may be, but is not limited to, for example, a Corning glass manufactured by Asahi Glass Inc. In addition, the encapsulation substrate 100 may also be an encapsulation substrate on which a touch screen panel (TSP) is printed.

According to an embodiment of the present invention, AR coating film may be further performed on the encapsulation substrate 100.

The present invention will be described in further detail with reference to the following examples. The following examples are for illustrative purposes only and are not intended to limit the scope of the invention.

### EXAMPLES

### Example 1

### When a Layer having UV Shielding Capability Contacts One Surface of an Encapsulation Substrate

A ITO glass substrate (Asahi Glass Inc., surface resistance: 15 Ω/cm², thickness: 1200 Å) was cut to a size of 50 mm×50 mm×0.7 mm and then sonicated in isopropyl alcohol and pure water for 30 minutes, respectively, and then heated for 4 hours. The resulting glass substrate was loaded into a vacuum deposition device.

A low work function Al was thermal deposited on the, glass substrate to form an anode having a thickness of 1500 Å.

N,N′-diphenyl-N,N′-bis-[4-(phenyl-m-tolyl-amino)-phenyl]-biphenyl-4,4′-diamine (DNTPD) was vacuum-deposited on the anode to form a HIL having a thickness of 650 Å. Then 4,4′-bis[N-(1-naphthyl)-N-phenylamino]biphenyl (NPB) was vacuum-deposited on the HIL to form a HTL having a thickness of 650 Å.

9,10-di-naphthalene-2-yl-anthracene (DNA) as a blue fluorescent host, and 4,4′-bis(2,2-diphenylvinyl)biphenyl (DPVBi) as a blue fluorescent dopant, were co-deposited in a weight ratio of 98:2 on the HTL to form an EML having a thickness of 200 Å.

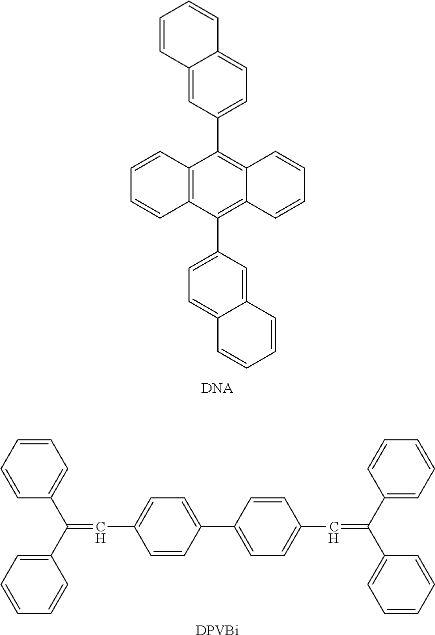

Then, bis(10-hydroxyben-zo[h]quinolinato)beryllium (Bebq2) was deposited on the EML to form an ETL having a thickness of 10 Å, and then LiF was deposited on the ETL to form an EIL having a thickness of 10 Å, and then Mg—Ag was deposited in a weight ratio of 10:1 on the EIL to form a cathode having a thickness of 200 Å, thereby completing the manufacturing of an organic light-emitting unit on the substrate.

An optical film having an UV shielding capability was attached to an inner surface of an encapsulation substrate using an adhesive and then an adhesive for encapsulation coupling was applied to the optical film, wherein the thickness of the optical film having an UV shielding capability and the adhesive layer was in the range of 20 to 50 μm.

Meanwhile, when a polarizing capability was provided to the optical film having an UV shielding capability, the thickness of the optical film with both an UV shielding capability and a polarizing capability was increased by about 200 μm so that the total thickness of the optical film and the adhesive layer was in the range of about 220 to about 250 μm.

The resultant structure was aligned and vacuum-coupled to the formed organic light-emitting unit. In order to remove micro bubbles that might exist, an autoclave process was performed on the coupled structure for thermal curing at a temperature of about 80 to about 100° C., thereby completing the manufacturing of an organic light-emitting device.

Meanwhile, for ease of cutting the glass substrate, the inner surface of the encapsulation substrate was etched before the encapsulation substrate was loaded, in consideration of the total thickness (220 to 250 μm) of the optical film and the adhesive layer.

### Example 2

### When Layer having UV Shielding Capability and Polarizing Capability Contacts One Surface of Organic Light-Emitting Unit

An optical film having an UV shielding capability and a polarizing capability was cut to the same size as the size of an emission area of the organic light-emitting unit formed on the glass substrate as stated in Example 1.

An adhesive was applied to an encapsulation substrate and the optical film was attached to the adhesive layer. An adhesive was applied to an edge of a surface of the optical film facing the organic light-emitting unit in order to attach the resultant structure including the encapsulation substrate to the structure including the organic light-emitting unit and the glass substrate.

The total thickness of the optical film and the adhesive layer was in the range of about 220 to about 250 μm. The prepared encapsulation substrate was aligned and vacuum-coupled to the structure including the organic light-emitting unit and the substrate.

In order to remove micro bubbles that might exist an autoclave process was performed on the coupled structure for thermal curing at a temperature of about 80 to about 100° C., thereby completing the manufacturing of an organic light-emitting device.

### Example 3

### When Layer having UV Shielding Capability and Polarizing Capability is Spaced Apart from Encapsulation Substrate and Organic Light-Emitting Unit

A first adhesive was applied to an encapsulation substrate. An optical film having an UV shielding capability and a polarizing capability was cut to the same size as the size of the emission area of the organic light-emitting unit formed on the glass substrate as stated in Example 1. The optical film was attached to the first adhesive layer, which is attached to the encapsulation substrate. A second adhesive was applied to an organic light-emitting unit. An adhesive was applied to an edge of a surface of the optical film facing the organic light-emitting unit in order to attach the resultant structure including the encapsulation substrate to the structure including the organic light-emitting unit and the glass substrate.

The thickness of the optical film was in the range of about 220 to about 300 μm. The resultant structure was aligned and vacuum-coupled to the structure including the organic light-emitting unit and the substrate.

In order to remove micro bubbles that might exist, an autoclave process was performed on the coupled structure for thermal curing at a temperature of about 80 to about 100° C., thereby completing the manufacturing of an organic light-emitting device.

Meanwhile, when there was a need to limit the sizes of the first and second adhesive films for ease of cutting the glass substrate, an inner surface of the encapsulation substrate was etched before the encapsulation substrate was loaded, in consideration of the thickness (220 to 250 μm) of the optical film.

### Example 4

### AR Coating Film is Performed on Encapsulation Substrate

An organic light-emitting device was manufactured in the same manner as stated in Example 1, except that AR coating film was performed on a surface of the encapsulation substrate facing away from the organic light-emitting unit.

### Comparative Example 1

An organic light-emitting device was manufactured in the same manner as stated in Example 1, except that the adhesive was applied to the organic light-emitting unit, the encapsulation substrate was formed on the adhesive layer, and then the optical layer having an UV shielding capability and a polarizing capability was attached to a surface of the encapsulation substrate away from the organic light-emitting unit by using an adhesive, wherein the total thickness of the optical layer and the adhesive was in the range of about 220 and about 250 μm.

### Evaluatin Example

Rigidity Evaluation

Rigidity tests were performed on the organic light-emitting devices prepared according to Examples 1 through 4 and Comparative Example 1.

When each of the organic light-emitting devices was dropped 10 times, the organic light-emitting device of Comparative Example 1 was broken six times, and each of the organic light-emitting devices of Examples 1 through 4 was broken twice.

<Test Conditions>

Dropping tests were performed based on a 4.0″ panel standard

Drop height: 1.8

10 cycles of top side dropping and bottom side dropping

Resistance-to-Weather Change Evaluation

Resistance-to-weather change tests were performed on the organic light-emitting devices of Examples 1 to 4 and Comparative Example 1 using a pressure cooker test (PCT): 2 atm. 120° C., and one hour.

20 samples of each organic light-emitting device were used and their lighting states and encapsulation states were identified. As a result, it was seen that all the organic light-emitting devices used had similar evaluation results.

All of the organic light-emitting devices of Examples 1 to 4 and Comparative Example 1 had an external light shielding effect due to inclusion of an optical film. However, in terms of rigidity, the organic light-emitting devices of Examples 1 to 4 showed better characteristics than the organic light-emitting device of Comparative Example 1.

An organic light-emitting device according to an embodiment of the present invention has an external light shielding effect due to inclusion of a layer having at least one capability selected from a group consisting of an UV shielding capability and a polarizing capability in an encapsulation layer and also has a high visible light transmission rate.

While the present invention has been particularly shown and described with reference to exemplary embodiments thereof, it will be understood by those of ordinary skill in the art that various changes in form and details may be made therein without departing from the spirit and scope of the present invention.

What is claimed is:

1. An organic light-emitting device comprising:
a substrate;
an encapsulation substrate;
an organic light-emitting unit interposed between the substrate and the encapsulation substrate; and
a layer having an ultraviolet (UV) shielding capability interposed between the encapsulation substrate and the organic light-emitting unit.

2. The organic light-emitting device of claim wherein the layer further comprises a polarizing capability.

3. The organic light-emitting device of claim 1, wherein the layer contacts a surface of the encapsulation substrate.

4. The organic light-emitting device of claim 1, wherein the layer contacts a surface of the organic light-emitting unit.

5. The organic light-emitting device of claim 1, wherein the layer is spaced apart from both the encapsulation substrate and the: organic light-emitting unit.

6. The organic light-emitting device of claim 1, wherein the layer contacts a surface of the encapsulation substrate, and
the surface of the encapsulation substrate has a cavity structure or a trench structure formed by etching.

7. The organic light-emitting device of claim 1, wherein an adhesive is applied to the layer and the total thickness of the formed adhesive layer and the layer is in a range of about 20 μm to about 100 μm.

8. The organic light-emitting device of claim 2, wherein an adhesive is applied to the layer having an UV shielding capability and a polarizing capability, and the total thickness of the formed adhesive layer and the layer is in a range of about 220 μm to about 300 μm.

9. The organic light-emitting device of claim 1, wherein an anti-reflection coating film is further formed on the encapsulation substrate.
